(19) United States
(12) Patent Application Publication
(10) Pub. No.: US 2025/0099999 A1
(43) Pub. Date: Mar. 27, 2025

(54) TREATMENT LIQUID SUPPLY APPARATUS, SUBSTRATE PROCESSING APPARATUS INCLUDING THE SAME AND METHOD FOR PROCESSING TREATMENT LIQUID

(71) Applicant: SEMES CO., LTD., Cheonan-si (KR)

(72) Inventors: Yong Hoon HONG, Seoul (KR); Jin Ah HAN, Cheonan-si (KR); Byung Sun BANG, Hwaseong-si (KR); Hyun Woo TAK, Cheonan-si (KR)

(21) Appl. No.: 18/675,465

(22) Filed: May 28, 2024

(30) Foreign Application Priority Data
Sep. 27, 2023 (KR) 10-2023-0130103

(51) Int. Cl. B05B 14/30; B05B 12/08

(52) U.S. Cl. CPC B05B 14/30; B05B 12/084

(57) ABSTRACT

A treatment liquid supply apparatus includes a discharge line through which treatment liquid is discharged from a substrate processing apparatus; a first tank storing recovered treatment liquid, recovered through the discharge line; a treatment liquid supply unit supplying new treatment liquid to the discharge line through a first transfer line; a first heating unit disposed between the treatment liquid supply unit and the discharge line and controlling a temperature of the new treatment liquid passing through the first transfer line; and a second tank resupplying the recovered treatment liquid supplied from the first tank through a second transfer line to the substrate processing apparatus through a supply line.

### CROSS-REFERENCE TO RELATED APPLICATIONS

The application claims benefit of priority to Korean Patent Application No. 10-2023-0130103 filed Sep. 27, 2023 in the Korean Intellectual Property Office, the disclosure of which is incorporated herein by reference in its entirety.

### BACKGROUND

### 1. Field

Embodiments of the present disclosure relate to a treatment liquid supply apparatus, a substrate processing apparatus including the same and a method for processing treatment liquid.

Generally, in a process for manufacturing a semiconductor substrate, various treatment liquids may be used in a wet etching process and a cleaning process to remove a film from a surface of a substrate. The treatment liquid discharged after the treatment liquid is used in a treatment process may be recovered and reused. In this case, since a process to treat a concentration of the treatment liquid to a reusable concentration is necessary to reuse the liquid, the concentration may be adjusted by supplying new treatment liquid to the treatment liquid.

The treatment liquid discharged from the substrate processing apparatus may be recovered and stored in the recycling tank, may sequentially move to a sub tank and a main tank, a process of adjusting a concentration may be sequentially performed, and the treatment liquid may be supplied back to the substrate processing apparatus. In the process, as treatment liquid at room temperature is frequently stored in the recycling tank, the temperature of the treatment liquid may decrease to approximately 40 to 50° C. (up to approximately 30-40° C. depending on the amount of liquid), which is lower than the process temperature (about 55° C.) required for substrate processing. Here, the temperature may drop to about 30-40° C. Accordingly, it may take a substantial amount of time to control the temperature of the treatment liquid in the recycling tank and sub tank. Also, as the concentration of the recovered treatment liquid is adjusted while the liquid moves sequentially to the recycling tank, sub tank and main tank, the time required to control and stabilize the concentration of the treatment liquid may also increase, which may be problematic.

### 2. Description of Related Art

An embodiment of the present disclosure is to provide a treatment liquid supply apparatus which may swiftly adjust a temperature of treatment liquid to a target temperature and to stabilize the temperature of the treatment liquid before the liquid flows into a recycling tank without a sub tank for temperature control, and a substrate processing apparatus including the same and a method for processing treatment liquid.

### SUMMARY

According to an embodiment of the present disclosure, a treatment liquid supply apparatus includes a discharge line through which treatment liquid is discharged from a substrate processing apparatus; first a tank storing recovered treatment liquid, recovered through the discharge line; a treatment liquid supply unit supplying new treatment liquid to the discharge line through a first transfer line; a first heating unit disposed between the treatment liquid supply unit and the discharge line and controlling a temperature of the new treatment liquid passing through the first transfer line; and a second tank resupplying the recovered treatment liquid supplied from the first tank through a second transfer line to the substrate processing apparatus through a supply line.

According to an embodiment of the present disclosure, a method for processing treatment liquid includes discharging treatment liquid from a substrate processing apparatus through a discharge line; supplying new treatment liquid to a discharge line by a treatment liquid supply unit; adjusting a temperature of the new treatment liquid supplied to the discharge line by a first heating unit; adjusting a temperature of the recovered treatment liquid recovered into the first tank through the discharge line to a predetermined temperature; and transferring the recovered treatment liquid of which a concentration and a temperature are controlled to the second tank.

According to an embodiment of the present disclosure, a substrate processing apparatus includes a process chamber; a processing vessel disposed in the process chamber, accommodating a substrate therein, including a liquid outlet on a bottom surface thereof, and having an open upper portion; a support unit supporting the substrate and including a support shaft disposed in the processing vessel and rotating, and a spin head connected to the support shaft; a nozzle unit disposed on an external side of the processing vessel and including a moving nozzle device discharging treatment liquid to the substrate; and a treatment liquid supply apparatus including a discharge line connected to the liquid outlet and discharging the treatment liquid, a first tank storing recovered treatment liquid, recovered through the discharge line, a treatment liquid supply unit supplying new treatment liquid to the discharge line through a first transfer line, a first heating unit disposed between the treatment liquid supply unit and the discharge line and controlling a temperature of the new treatment liquid passing through the first transfer line, and a second tank resupplying the recovered treatment liquid supplied from the first tank through a second transfer line to the substrate processing apparatus through a supply line, wherein the discharge line is configured as a pipe for discharging the treatment liquid, disposed between the substrate processing apparatus and the first tank, and the first transfer line is configured as a pipe for supplying the new treatment liquid, disposed between the treatment liquid supply unit and the discharge line, wherein one end of the discharge line is connected to the substrate processing apparatus, the other end of the discharge line is connected to the first tank, one end of the first transfer line is connected to the treatment liquid supply unit, and the other end of the first transfer line is connected to the discharge line and is connected between one end and the other end of the discharge line, wherein the first heating unit is configured as a jacket heater surrounding at least a portion of an external surface of the first transfer line, and wherein the treatment liquid discharged from the processing vessel sequentially passes through the first tank and the second tank and is supplied back to the nozzle unit.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a cross-sectional diagram illustrating a substrate processing apparatus according to an embodiment of the present disclosure;

FIG. 2 is a diagram illustrating a treatment liquid supply apparatus and a substrate processing apparatus according to an embodiment of the present disclosure;

FIG. 3 is a diagram illustrating a treatment liquid supply apparatus and a substrate processing apparatus according to an embodiment of the present disclosure;

FIG. 4 is a diagram illustrating a treatment liquid supply apparatus and treatment liquid of a substrate processing apparatus according to an embodiment of the present disclosure;

FIG. 5 is a diagram illustrating a treatment liquid supply apparatus and treatment liquid of a substrate processing apparatus according to an embodiment of the present disclosure;

FIG. 6 is a diagram illustrating a treatment liquid supply apparatus and a substrate processing apparatus according to an embodiment of the present disclosure;

FIG. 7 is a diagram illustrating a treatment liquid supply apparatus and a substrate processing apparatus according to an embodiment of the present disclosure;

FIG. 8 is a flowchart illustrating a method for processing treatment liquid according to an embodiment of the present disclosure; and

FIG. 9 is a flowchart illustrating the method for processing treatment liquid illustrated in FIG. 8.

### DETAILED DESCRIPTION

Hereinafter, embodiments of the present disclosure will be described as below with reference to the attached drawings. Various embodiments will be described with reference to accompanying drawings. The redundant descriptions and detailed descriptions of known functions and elements that may unnecessarily make the gist of the present disclosure obscure will be omitted. same elements will be indicated by same reference numerals. The terms “upper,” “upper portion,” “upper end,” “lower,” “lower portion,” “lower end,” and the similarly to are indicated with respect to the drawings, the terms “internal,” “external,” and the similarly to are indicated with respect to a periphery of a component, and the terms may vary depending on directions in which the components are disposed.

The terms, “include,” “comprise,” “is configured to,” or the similarly to of the description are used to indicate the presence of features, numbers, steps, operations, elements, portions or combination thereof, and do not exclude the possibilities of combination or addition of one or more features, numbers, steps, operations, elements, portions or combination thereof.

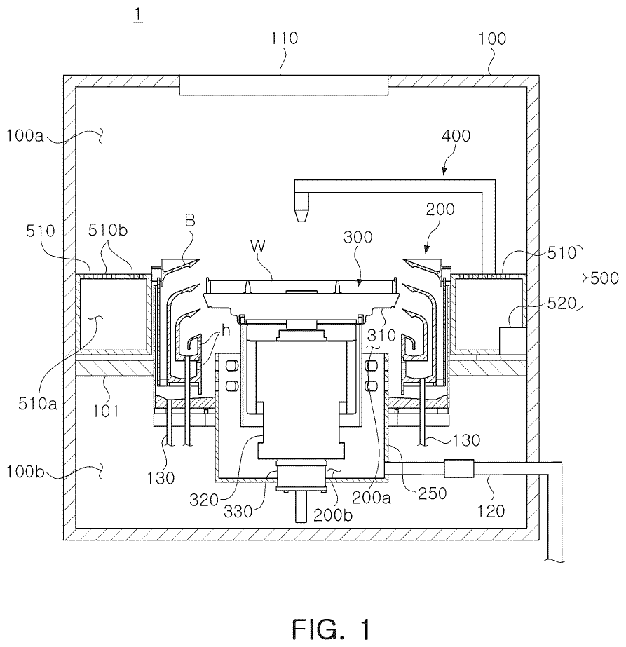

FIG. 1 is a cross-sectional diagram illustrating a substrate processing apparatus according to an embodiment.

Referring to FIG. 1, a substrate processing apparatus 1 may be applied to a cleaning process and may perform a cleaning process by spraying liquid required for the cleaning process to the substrate through a liquid supply line. However, an embodiment thereof is not limited thereto, and the substrate processing apparatus 1 may be applied to various processes in which liquid is provided, such as an etching process.

The substrate processing apparatus 1 may include a process chamber 100 processing the substrate W using liquid. In the process chamber 100, a process may be performed on the substrate W while maintaining the substrate W horizontally. The process chamber 100 may be used to perform various processes on the substrate W using various treatment liquids.

The process chamber 100 may provide a sealed internal space, and a fan filter unit 110 may be installed in an upper portion. The fan filter unit 110 may generate vertical airflow in the process chamber 100. The fan filter unit 110 may be configured as a unit obtained by modularization of a filter and an air supply fan, and may filter clean air and supply the filtered air into the process chamber 100. The clean air may pass through the fan filter unit 110, may be supplied into the process chamber 100 and may form a vertical airflow. The vertical airflow may provide a uniform airflow on an upper portion of the substrate W, and contaminants (fumes) generated in the process of processing the surface of the substrate W by treatment fluid may be discharged along with air through a bowl B of a processing vessel 200 to a discharge line 130 and may be removed, such that high cleanliness may be maintained in the processing vessel.

The process chamber 100 may include a process region 100a and a maintenance region 100b partitioned by a horizontal partition 101. The maintenance region 100b may be a space in which the discharge line 130 and an exhaust line 120 connected to the processing vessel 200 are disposed, and the maintenance region 100b may be isolated from the process region 100a in which the substrate W is processed.

Also, the substrate processing apparatus 1 may include a processing vessel 200, a support unit 300, and a nozzle unit 400 in the process chamber 100. The processing vessel 200 may be installed in the process chamber 100, may have a cylindrical shape having an open upper portion, and may provide a processing space for processing the substrate W. The opened upper surface of the processing vessel 200 may be provided as an export and import passage for the substrate W. Here, the support unit 300 may be disposed in the processing space. In this case, the support unit 300 may support the substrate W and may rotate the substrate W when performing the process.

Also, the processing vessel 200 may provide an upper space 200a in which the spin head 310 of the support unit 300 is disposed, and a lower space 200b in which the exhaust collection unit 250 is connected to a lower portion to enable forced exhaust. The exhaust collection unit 250 may be connected to the exhaust line 120 extending externally of the process chamber 100. In the upper space 200a of the processing vessel 200, an annular-shaped bowl B entering and absorbing the treatment liquid and gas scattering on the rotating substrate W may be disposed in multiple stages. The bowl B may include exhaust ports h communicating with a common annular space (corresponding to a lower space of the processing vessel). Here, the bowl B may be a portion into which airflow including liquid and fumes scattered from the substrate W flows.

The support unit 300 may be installed in the processing vessel 200. The support unit 300 may support the substrate W while the process is performed, and may rotate by the driving member 330 while the process is performed. Also, the support unit 300 may include a spin head 310 having a circular upper surface. A support shaft 320 supporting the spin head 310 may be connected to a lower portion of the spin head 310, and the support shaft 320 may rotate by the driving member 330 connected to a lower end thereof. In this case, the driving member 330 may include a motor, and the spin head 310 and the substrate W may rotate as the support shaft 320 rotates by the driving member 330.

The nozzle unit 400 may discharge liquid (treatment liquid, etc.) to the substrate W supported on the support unit 300. The nozzle unit 400 may be a moving nozzle device 400M or a fixed nozzle device (not illustrated). A plurality of moving nozzle devices 400M may be installed on an external side of the processing vessel 200.

The chamber fluid collector 500 may include a fluid collection container 510 and an intake portion 520.

The fluid collection container 510 may be disposed in the process chamber 100, the intake portion 520 may be installed on the fluid collection container 510, and provide suction force for the fluid collection container 510 to suction the liquid in the process chamber 100.

As an embodiment, the fluid collection container 510 may have an internal space 510a to form a space in which the liquid in the process chamber 100 is collected, and a plurality of inlet holes 510b may be formed in a portion to allow the liquid in the process chamber 100 to flow. Also, the intake portion 520 may be configured to provide suction force for the fluid collection container 510 to suction the liquid in the process chamber 100. That is, the intake portion 520 may be configured to generate negative pressure in the internal space 510a of the fluid collection container 510. As described above, the internal space 510a of the fluid collection container 510 may be formed at a lower pressure than external pressure by the intake portion 520, and the fluid collection container 510 may suction the liquid in the process chamber 100 through the inlet hole 510b, such that liquid generated after the substrate processing process may be removed from the process chamber 100, and the internal region of the process chamber 100 may be prevented from being contaminated by salt contained in the liquid.

Also, although not illustrated in the drawing, the intake portion 520 may have a structure connected to an environmental exhaust unit. An environmental exhaust unit may be installed in the process chamber 100 to exhaust gas in the process chamber 100 externally of the process chamber 100, and the environmental exhaust unit and the intake portion 520 may be connected to each other. In this case, the intake portion 520 may provide necessary suction force for the fluid collection container 510 using the exhaust force of the environmental exhaust unit without having a driving source generating suction force. The for environmental exhaust unit may be the exhaust line 120 of the substrate processing apparatus 1 described above, or may alternatively be an exhaust port for exhausting gas in the process chamber 100.

In the substrate processing apparatus 1 described above, the processing liquid (or treatment liquid) used when various processes is performed on the substrate W may be discharged externally of the substrate processing apparatus 1 after being used. In this case, the used treatment liquid may be discharged externally of the substrate processing apparatus 1 through the liquid outlet (not illustrated) provided in the processing vessel 200 and the discharge line L10 connected thereto. For example, the liquid outlet may be formed on a bottom surface of the processing vessel 200. In this case, the discharged treatment liquid may be recovered in the treatment liquid supply apparatus 1000, 1000a, 1000b, 1000c, 1000d, and 1000e included in the substrate processing apparatus 1, and may be processed to a reusable state in the substrate processing apparatus 1. Hereinafter, various processes in which processing liquid (treatment liquid) is used in the substrate processing apparatus 1 may be referred to as a process of processing the substrate W.

The treatment liquid supply apparatus 1000, 1000a, 1000b, 1000c, 1000d, and 1000e may recover the treatment liquid discharged from the substrate processing apparatus 1 and may add a new treatment liquid to the recovered treatment liquid (hereinafter, referred to as recovered treatment liquid), thereby adjusting a concentration. Also, the treatment liquid supply apparatus 1000, 1000a, 1000b, 1000c, 1000d, and 1000e may heat the new treatment liquid and the recovered treatment liquid to the process temperature. Through the processing process, the recovered treatment liquid may be processed into a reusable state in the treatment liquid supply apparatus 1000, 1000a, 1000b, 1000c, 1000d, and 1000e. The method for processing treatment liquid may be described in greater detail below.

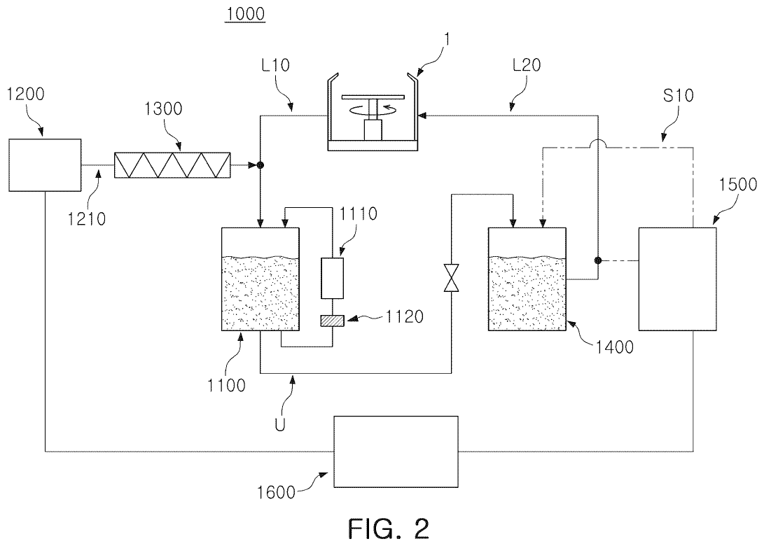

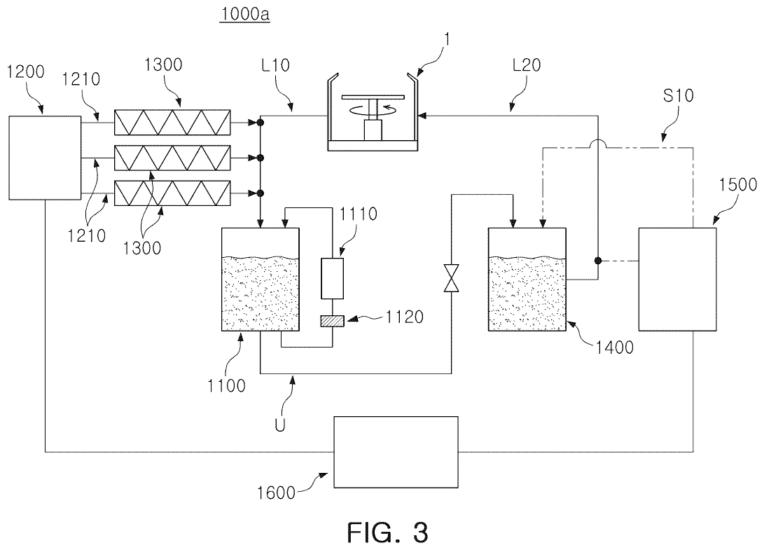

FIG. 2 is a diagram illustrating a treatment liquid supply apparatus and a substrate processing apparatus according to an embodiment. FIG. 3 is a diagram illustrating a treatment liquid apparatus supply and a substrate processing apparatus according to an embodiment.

Referring to FIG. 2, an embodiment (hereinafter, treatment liquid supply apparatus 1000 according to embodiment 1) may include a first tank 1100, a treatment liquid supply unit 1200, a first heating unit 1300, and a second tank 1400. Also, the treatment liquid supply apparatus 1000 may further include a concentration detection unit 1500 and a control unit 1600.

The first tank 1100 may recover the treatment liquid discharged after being used in the process of processing the substrate W in the substrate processing apparatus 1. The first tank 1100 may be connected to a discharge line L10 for discharging treatment liquid from the substrate processing apparatus 1. In this case, the discharge line L10 may be a pipe for discharging treatment liquid disposed between the substrate processing apparatus 1 and the first tank 1100. However, an embodiment thereof is not limited thereto, and the discharge line L10 may be, for example, in the form of a hose for moving treatment liquid. One end of the discharge line L10 may be connected to the substrate processing apparatus 1, and the other end of the discharge line L10 may be connected to the first tank 1100. In this case, a portion to which the one end of the discharge line L10 is connected may be a liquid outlet (not illustrated) provided in the processing vessel 200.

The discharged treatment liquid may move through the discharge line L10 and may be stored in the first tank 1100. The treatment liquid recovered into the treatment liquid supply apparatus 1000 may be referred to as recovered treatment liquid, as described above.

For example, the first tank 1100 may include a pressure reducing member (not illustrated) such as an aspirator. In this case, the treatment liquid may move to the first tank 1100 by reducing internal pressure of the first tank 1100 by a pressure reducing member to generate a difference in pressure. As another example, a pump (not illustrated) may be provided in the discharge line L10, and by operating the pump, the treatment liquid may pass through the discharge line L10 and may move to the first tank 1100. However, an embodiment thereof is not limited thereto, and the treatment liquid may be transferred from the substrate processing apparatus 1 to the first tank 1100 in various manners. In this case, the discharge line L10 may include a filter (not illustrated) to filter the treatment liquid before moving to the first tank 1100.

Generally, treatment liquid used in the process of processing the substrate W may include various components such as de-ionized water (DIW) and various metal atoms including H₂O₂ and Ti. After the treatment liquid is supplied to substrate processing apparatus 1, a portion of the used treatment liquid may be discarded, but the other portion of the treatment liquid may be recovered into the first tank 1100. In this case, as the process of processing the substrate W is performed, a portion of DIW may evaporate or the TiN contained in the substrate W may be ionized due to an etching process. Accordingly, a concentration of Ti ions in the treatment liquid may increase, and the concentration of Ti ions in the treatment liquid may change for various reasons, such as decomposition of H₂O₂ by Ti ions. Accordingly, the concentration of Ti ion in the discharged treatment liquid may be different from the concentration of Ti ion when supplied to the substrate processing apparatus 1.

To address the above issue, the treatment liquid supply unit 1200 may replenish the discharged treatment liquid with new treatment liquid to increase the amount of treatment liquid, and may adjust the concentration of Ti ion in the treatment liquid through the addition. In this case, the treatment liquid supply unit 1200 may include a first transfer line 1210.

The first transfer line 1210 may be a passage through which the treatment liquid supplied from the treatment liquid supply unit 1200 passes, and may be connected to the discharge line L10. The treatment liquid supply unit 1200 may supply new treatment liquid to the discharge line L10 through the first transfer line 1210. Accordingly, a concentration of the treatment liquid passing through the discharge line L10 may be adjusted to a predetermined concentration before flowing into the first tank 1100. Here, the newly supplied treatment liquid may be a mixed liquid including DIW, H₂O₂, and BEOL organic chemicals (post TiN strip). Also, the predetermined concentration may be a concentration of Ti ion in the liquid which may be sufficient for the treatment liquid to be resupplied to the substrate processing apparatus 1 and to be reused in the process of processing the substrate W. The predetermined concentration may be, for example, less than 30 ppm.

The first transfer line 1210 may be a pipe for moving treatment liquid disposed between the treatment liquid supply unit 1200 and the discharge line L10. However, an embodiment thereof is not limited thereto, and the first transfer line 1210 may be, for example, in the form of a hose for moving the treatment liquid. One end of the first transfer line 1210 may be connected to the treatment liquid supply unit 1200. The other end of the first transfer line 1210 may be connected to the discharge line L10, and in this case, the other end of the first transfer line 1210 may be connected to the one end of the discharge line L10 [i.e., the end connected to the substrate processing apparatus 1] and the other end [i.e. the end connected to the first tank 1100].

The first heating unit 1300 may control the temperature of new treatment liquid supplied from the treatment liquid supply unit 1200 before meeting the treatment liquid discharged from the substrate processing apparatus 1. In this case, the first heating unit 1300 may be disposed between the treatment liquid supply unit 1200 and the discharge line. The first heating unit 1300 may heat the treatment liquid passing through the first transfer line 1210 to a predetermined temperature. The first heating unit 1300 may be, for example, a jacket heater. In this case, the predetermined temperature may be a temperature higher than room temperature and may be a process temperature usable for the process of processing the substrate W, and for example, the predetermined temperature may be 35° C. to 75° C. Preferably, the predetermined temperature may be 55° C.±0.5° C., and more preferably 55° C.

The temperature of the discharged treatment liquid may decrease while being used and moving in the substrate processing apparatus 1, and after being discharged in a state lower than the above process temperature (e.g., room temperature), the treatment liquid may move along the discharge line L10. In this case, as described above, new treatment liquid heated to a predetermined temperature may be supplied to the discharge line L10. Accordingly, in the discharge line L10, the treatment liquid discharged from the substrate processing apparatus 1 may be mixed with the new treatment liquid, and the temperature of the discharged treatment liquid may increase. As described above, through addition of the new treatment liquid in a preheated state, the temperature of the treatment liquid may be adjusted for the first time before the treatment liquid flows into a substrate first tank 1100. Thereafter, the treatment liquid mixed with the treatment liquid and the concentration and temperature thereof adjusted may flow into the first tank 1100 and may be stored.

The first tank 1100 may include a second heating unit 1110 and a temperature sensor 1120. The second heating unit 1110 may heat the recovered treatment liquid stored in the first tank 1100, thereby controlling the temperature of the treatment liquid for the second time. The temperature sensor 1120 may measure the temperature of the recovered treatment liquid in the first tank 1100. The temperature sensor 1120 may transmit a temperature measurement value to the control unit 1600, which will be described later. The control unit 1600 may determine, based on the received temperature measurement value, whether the temperature of the recovered treatment liquid has reached the predetermined temperature. The control unit 1600 may control the second heating unit 1110 based on the determination result.

For example, when the temperature measurement value of the control unit 1600 is lower than the predetermined temperature, the second heating unit 1110 may heat the recovered treatment liquid stored in the first tank 1100 such that the temperature becomes the predetermined temperature. As another example, when the temperature measurement value is the same as or approximate to a predetermined temperature, the control unit 1600 may control the second heating unit 1110 to maintain the recovered treatment liquid in the first tank 1100 to be warm to maintain the predetermined temperature. As described above, the recovered treatment liquid in the first tank 1100 of which the temperature and the concentration has been adjusted may move to the second tank 1400 through the second transfer line U.

The recovered treatment liquid supplied from the first tank 1100 may be temporarily stored in a second tank 1400 before being supplied again to the substrate processing apparatus 1. In this case, the second tank 1400 may be connected to the first tank 1100 through the second transfer line U. More specifically, the recovered treatment liquid of which the concentration and the temperature have been adjusted in the discharge line L10 and the first tank 1100 may move to the second tank 1400 through the second transfer line U and may be stored. In this case, a transfer pump (not illustrated) may be installed in the second transfer line U, and the recovered treatment liquid may move from the first tank 1100 to the second tank 1400.

The second tank 1400 may resupply the recovered treatment liquid (hereinafter, referred to as reprocessed treatment liquid) which has been processed by controlling the concentration and the temperature to the substrate processing apparatus 1 through the supply line L20. The reprocessed treatment liquid supplied may be reused in the process of processing the substrate W in the substrate processing apparatus 1.

A concentration detection unit 1500 may measure a concentration of recovered treatment liquid. For example, the concentration measured by the concentration detection unit 1500 may be the concentration of Ti ions contained in the recovered treatment liquid. In this case, the concentration detection unit 1500 may include at least one concentration detection line. In the treatment liquid supply apparatus 1000 according to embodiment 1, the concentration detection unit 1500 may include one concentration detection line, the first concentration detection line S10.

The concentration detection unit 1500 may detect the concentration of the recovered treatment liquid stored in the second tank 1400 through the first concentration detection line S10. In this case, one end of the first concentration detection line S10 may be connected to the concentration detection unit 1500, and the other end of the first concentration detection line S10 may be connected to the supply line L20. In this case, when the recovered treatment liquid stored in the second tank 1100 is discharged through the supply line L20, a portion of the discharged treatment liquid may flow into the concentration detection unit 1500 through the first concentration detection line S10. The concentration detection unit 1500 may detect the concentration of the recovered treatment liquid in the second tank 1400 using the treatment liquid. The concentration detection unit 1500 may transmit a first concentration measurement value, which may be the result value of measuring the concentration of the recovered treatment liquid in the second tank 1400, to the control unit 1600.

The control unit 1600 may adjust the concentration of the recovered treatment liquid stored in the second tank 1400 to be maintained constant. More specifically, the control unit 1600 may control the supply amount of treatment liquid of the treatment liquid supply unit 1200 based on the concentration measurement value measured the concentration detection unit 1500. In this case, the control unit 1600 may be implemented as, for example, a circuit substrate, a computer chip mounted on a circuit substrate, or software embedded in a computer chip or in a control computer, mounted on a control computer for the treatment liquid supply apparatus 1000, 1000a, 1000b, 1000c, 1000d, and 1000e. Alternatively, the control unit 1600 may be implemented in the form of software embedded in a control computer.

For example, when the first concentration measurement value received from the concentration detection unit 1500 is lower than the predetermined concentration, the control unit 1600 may increase the supply amount of treatment liquid supplied to discharge line L10 by controlling the treatment liquid supply unit 1200. As another example, when the first concentration measurement value received from the concentration detection unit 1500 is higher than the predetermined concentration, the supply amount of treatment liquid supplied to the discharge line L10 may be reduced by controlling the treatment liquid supply unit 1200. As another example, when the first concentration measurement value received from the concentration detection unit 1500 is a predetermined concentration, the treatment liquid supply unit 1200 may be controlled to maintain the amount of treatment liquid supplied to the discharge line L10.

Also, the control unit 1600 may control the second heating unit 1110 such that the temperature of the recovered treatment liquid stored in the first tank 1100 is predetermined temperature, and in this case, since the method of controlling the second heating unit 1110 based on the temperature measurement value is the same as described above, overlapping descriptions will not be provided.

Referring to FIG. 3, in the case of a treatment liquid supply apparatus 1000a) and a substrate processing apparatus 1 according to another embodiment (hereinafter, embodiment 2), the treatment liquid supply unit 1200 may include a plurality of first transfer line L20. In this case, a plurality of first heating units 1300 may also be provided, and the treatment liquid supplied to the discharge line L10 through each of the first transfer lines L20 may be heated to a predetermined temperature. In this case, the treatment liquid supply unit 1200 may supply treatment liquid to the discharge line L10 using a portion of the plurality of first transfer line L20, or the entirety of the first transfer line L20. Accordingly, the amount of treatment liquid supplied per unit time to the discharge line L10 may increase, such that the time required to adjust the concentration of treatment liquid may be reduced before flowing into the first tank 1100.

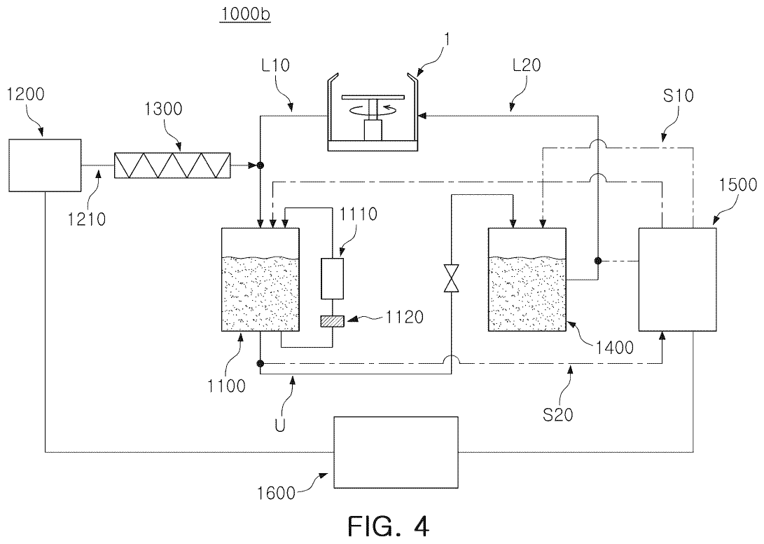

FIG. 4 is a diagram illustrating a treatment liquid supply apparatus and treatment liquid of a substrate processing apparatus according to an embodiment.

Referring to FIG. 4, the treatment liquid supply apparatus 1000b according to another embodiment (hereinafter, embodiment 3) may include a first tank 1100, a treatment liquid supply unit 1200, a first heating unit 1300, a second tank 1400, a concentration detection unit 1500 and a control unit 1600. Since most of the features may be the same or similar to embodiment 1 described above, overlapping descriptions will not be provided, and differences will be described.

In the treatment liquid supply apparatus 1000b according to embodiment 3, the concentration detection unit 1500 may include two concentration detection lines. In this case, the two concentration detection lines may be referred to as a first concentration detection line S10 and a second concentration detection line S20.

The first concentration detection line S10 may be connected to the supply line L20 as in embodiment 1 described above. The concentration detection unit 1500 may measure a concentration of recovered treatment liquid stored in the second tank 1400 through the first concentration detection line S10. The concentration detection unit 1500 may transmit the first concentration measurement value, which is the result value of measuring the concentration of the recovered treatment liquid in the second tank 1400, to the control unit 1600.

The second concentration detection line S20 may be connected to the first tank 1100. More specifically, the second concentration detection line S20 may be connected to the second transfer line U, and a portion of the recovered treatment liquid discharged from the first tank 1100 by the transfer pump may flow into the concentration detection unit 1500 through the second transfer line U. The concentration detection unit 1500 may detect a concentration of recovered treatment liquid stored in the first tank 1100 using the treatment liquid. The concentration detection unit 1500 may transmit the second concentration measurement value, which is the result value of measuring the concentration of the recovered treatment liquid in the first tank 1100, to the control unit 1600.

The control unit 1600 may adjust the supply amount of treatment liquid of the treatment liquid supply unit 1200 based on a difference in concentrations between the recovered treatment liquid stored in the first tank 1100 and the recovered treatment liquid stored in the second tank 1400. In this case, the difference in concentrations may be calculated using the first concentration measurement value and the second concentration measurement value.

The control unit 1600 may compare the calculated difference in concentrations with a predetermined reference value to determine the appropriate supply amount of treatment liquid to adjust the recovered treatment liquid to a reusable concentration. The predetermined reference value may be a reference value for the concentration of Ti ions contained in the recovered treatment liquid, and may be, for example, 30 ppm.

The control unit 1600 may feedback control the supply amount of treatment liquid such that the difference in concentrations may not exceed a predetermined reference value. For example, when the calculated difference in concentrations exceeds a predetermined reference value, the control unit 1600 may reduce the supply amount of treatment liquid supplied from the treatment liquid supply unit 1200 to the discharge line L10. Accordingly, as the concentration of the recovered treatment liquid stored in the first tank 1100 decreases, the difference in concentrations with respect to the recovered treatment liquid stored in the second tank 1400 may decrease. As another example, the control unit 1600 may control the treatment liquid supply unit 1200 to maintain the supply amount of treatment liquid in the current state when the calculated difference in concentrations is less than a predetermined reference value. As another example, when the calculated difference in concentrations is a negative (−) value, that is, when the concentration of the recovered treatment liquid in the second tank 1400 is higher than the recovered treatment liquid in the first tank 1100, the control unit 1600 may increase the supply amount of treatment liquid supplied to the discharge line L10.

In this case, the control of increasing/decreasing the supply amount of treatment liquid in the control unit 1600 may be performed by calculating a difference in concentrations in real time using the first concentration measurement value and the second concentration measurement value measured continuously at predetermined time intervals by the concentration detection unit 1500. By continuously performing the difference in concentrations calculations and controlling the supply amount of treatment liquid based on the calculated values, the difference in concentrations between the recovered treatment liquid concentration in the first tank 1100 and the recovered treatment liquid concentration in the second tank 1400 may be adjusted to not exceed a predetermined reference value.

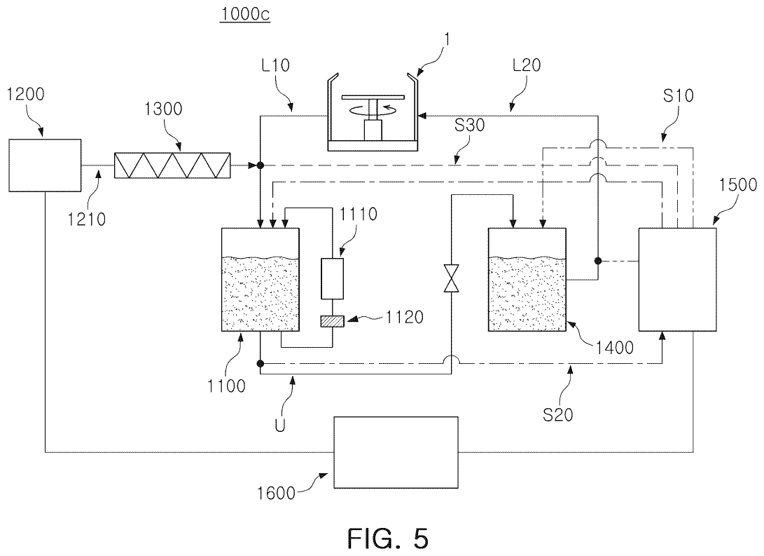

FIG. 5 is a diagram illustrating a treatment liquid supply apparatus and treatment liquid of a substrate processing apparatus according to an embodiment.

Referring to FIG. 5, the treatment liquid supply apparatus 1000c according to another embodiment (hereinafter, embodiment 4) may include a first tank 1100, a treatment liquid supply unit 1200, a first heating unit 1300, a second tank 1400, a concentration detection unit 1500 and a control unit 1600. Since most of the configurations are the same or similar to embodiment 1 or embodiment 3 described above, overlapping descriptions will not be provided, and differences will be described.

In the case of the treatment liquid supply apparatus 1000c according to embodiment 4, the concentration detection unit 1500 may include three concentration detection lines. In this case, the three concentration detection lines may be referred to as a first concentration detection line S10, a second concentration detection line S20, and a third concentration detection line S30.

Similarly to the embodiments 1 and 3 described above, the first concentration detection line S10 may be connected to the supply line L20, and accordingly, the concentration detection unit 1500 may measure the concentration of the recovered treatment liquid stored in the second tank 1400. Also, the second concentration detection line S20 may be connected to the second transfer line U, and accordingly, the concentration detection unit 1500 may detect the concentration of the recovered treatment liquid stored in the first tank 1100.

The third concentration detection line S30 may be connected to the discharge line L10. More specifically, one end of the third concentration detection line S30 may be connected to the end of the first transfer line L20, and the other end of the third concentration detection line S30 may be connected to the concentration detection unit 1500. Here, the end of the first transfer line L20 may be a point at which the first transfer line L20 and the discharge line L10 may be connected to each other and the supplied treatment liquid may start flowing into the discharge line L10. Using the third concentration detection line S30, the concentration detection unit 1500 may detect the concentration of the treatment liquid at a time point of mixing with new treatment liquid in the discharge line L10, or immediately after mixing with new treatment liquid. The concentration detection unit 1500 may transmit the third concentration measurement value, which may be a detection result value, to the control unit 1600. In this case, the third concentration measurement value may be measured at predetermined intervals and may be transmitted to the control unit 1600.

The control unit 1600 may monitor the concentration of the treatment liquid mixed with the new treatment liquid based on the received third concentration measurement value. Also, the control unit 1600 may monitor changes in concentration of the treatment liquid in the discharge line L10 by organizing the third concentration measurement values measured at predetermined intervals in time series.

The control unit 1600 may adjust the supply amount of treatment liquid of the treatment liquid supply unit 1200 based on a difference in concentrations between the recovered treatment liquid stored in the first tank 1100 and the recovered treatment liquid stored in the second tank 1400, which may be the same as or similar to embodiment 3 described above.

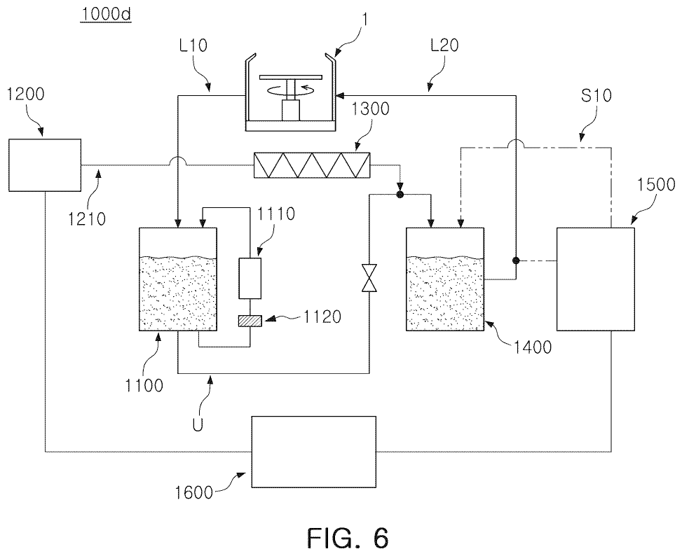

FIG. 6 is a diagram illustrating a treatment liquid supply apparatus and a substrate processing apparatus according to an embodiment.

Referring to FIG. 6, a treatment liquid supply apparatus 1000d according to another embodiment (hereinafter, embodiment 5) may include a first tank 1100, a treatment liquid supply unit 1200, a first heating unit 1300, a second tank 1400, a concentration detection unit 1500 and a control unit 1600. Since most of the configurations are the same as or similar to embodiment 1 described above, overlapping descriptions will not be provided, and differences will be described.

In the treatment liquid supply apparatus 1000d according to embodiment 5, the treatment liquid supply unit 1200 may supply new treatment liquid to the second tank 1400. In this case, a first transfer line 1210 may be disposed between the treatment liquid supply unit 1200 and the second tank 1400. More specifically, one end of the first transfer line 1210 may be connected to the treatment liquid supply unit 1200, and the other end of the first transfer line 1210 may be connected to the second transfer line U. Accordingly, a concentration of the new treatment liquid supplied through the first transfer line 1210 may be adjusted to a predetermined concentration by mixing with the recovered treatment liquid passing through the second transfer line U. As described above, the recovered treatment liquid of which concentration has been adjusted by supplying new treatment liquid before flowing into the second tank 1400 may be supplied to the second tank 1400.

In this case, the first heating unit 1300 may control a temperature of the recovered treatment liquid moving from the first tank 1100 to the second tank 1400. More specifically, after being discharged from the first tank 1100, the temperature may decrease slightly while moving along the second transfer line U. In this case, the new treatment liquid heated to a predetermined temperature may be supplied to the recovered treatment liquid moving along the second transfer line U. Accordingly, the temperature of the recovered treatment liquid may be stored in the second tank 1400 in a state in which the temperature is maintained at a predetermined temperature.

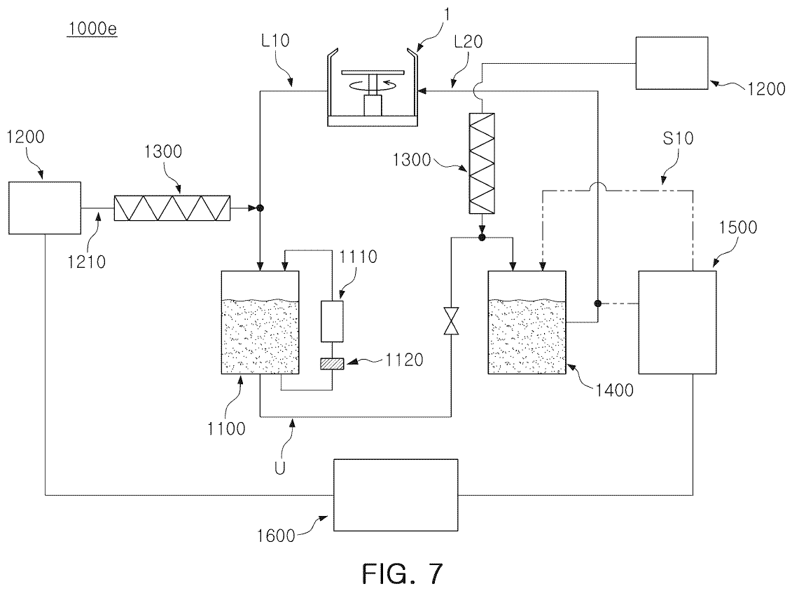

FIG. 7 is a diagram illustrating a treatment liquid supply apparatus and a substrate processing apparatus according to an embodiment.

Referring to FIG. 7, the treatment liquid supply apparatus 1000e according to another embodiment (hereinafter, embodiment 6) may include a first tank 1100, a treatment liquid supply unit 1200, a first heating unit 1300, a second tank 1400, a concentration detection unit 1500 and a control unit 1600. Since most of the configurations are the same or similar to embodiment 1 described above, overlapping descriptions will not be provided, and differences will be described.

In the treatment liquid supply apparatus 1000e according to embodiment 6, two treatment liquid supply units 1200 may be provided. In this case, one of the two treatment liquid supply units 1200 (e.g., the treatment liquid supply unit on the left in the drawing) may supply new treatment liquid to the discharge line L10 as in the above-described embodiments.

The other one of the two treatment liquid supply units 1200 (e.g., the treatment liquid supply unit on the right in the drawing) may be connected to the second transfer line U and may supply new treatment liquid to the recovered treatment liquid flowing into the second tank 1400. Accordingly, a concentration of the new treatment liquid supplied through the first transfer line 1210 may be adjusted by mixing with the recovered treatment liquid passing through the second transfer line U. As described above, the recovered treatment liquid of which a concentration has been adjusted by supplying new treatment liquid may be supplied to the second tank 1400. In this case, the new treatment liquid may be supplied heated to a predetermined temperature in the first heating unit 1300 before being supplied to the second transfer line U, which is the same as described above.

As described above, the concentration and the temperature by adding new treatment liquid to the treatment liquid passing through discharge line L10 and the recovered treatment liquid passing through second transfer line U using two treatment liquid supply units 1200, differences in concentrations and temperatures between the first tank 1100 and the second tank 1400 may be reduced.

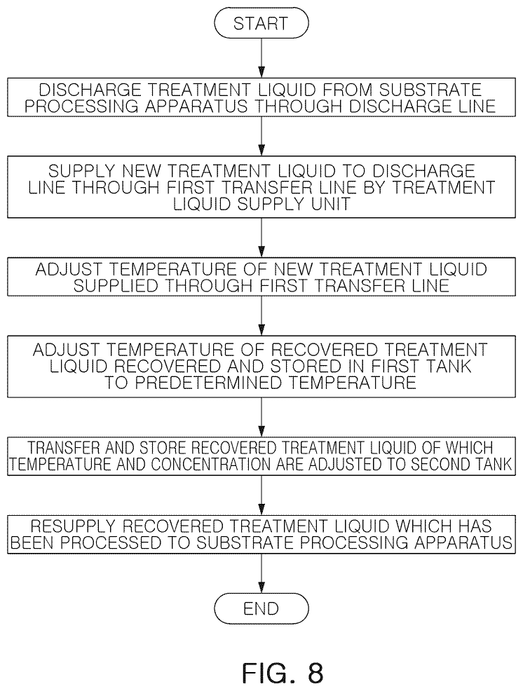

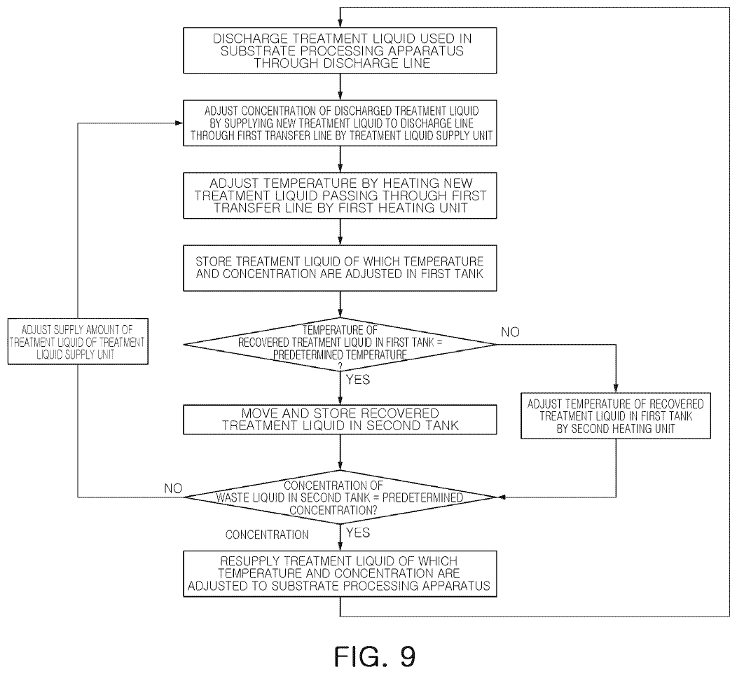

FIG. 8 is a flowchart illustrating a method for processing treatment liquid according to an embodiment. FIG. 9 is a flowchart illustrating the method for processing treatment liquid illustrated in FIG. 8.

Referring to FIGS. 8 and 9, the method for processing treatment liquid according to an embodiment may be described below. Embodiment 1 will be described for ease of description.

First, treatment liquid used in the process of processing a substrate W in a substrate processing apparatus 1 may be discharged through a discharge line L10. More specifically, the treatment liquid may be discharged to the substrate W through a nozzle unit 400 and may be discharged through a liquid outlet of the processing vessel 200 and the discharge line L10 connected thereto. In this case, a temperature of the discharged treatment liquid may be reduced while being used and moving in the substrate processing apparatus 1, and may be lower than a process temperature.

Thereafter, the treatment liquid supply unit 1200 may supply new treatment liquid to the discharge line L10. In this case, the new treatment liquid may be supplied through a first transfer line L20 connected to the discharge line L10. By mixing the new treatment liquid supplied as above with the treatment liquid passing through the discharge line L10, a concentration of the treatment liquid may be adjusted to a predetermined concentration before moving to the first tank 1100.

Thereafter, the first heating unit 1300 may control a temperature of the treatment liquid passing through the first transfer line L20. In this case, the first heating unit 1300 may heat the new treatment liquid to a predetermined temperature. In this case, the new treatment liquid may be heated to a predetermined temperature and may be stored as treatment liquid passing through the discharge line L10. Accordingly, the temperature may be controlled primarily by increasing the temperature of the treatment liquid discharged through the discharge line L10. Thereafter, the treatment liquid mixed with the new treatment liquid may be stored in the first tank 1100.

Thereafter, in the first tank 1100, the temperature of the recovered treatment liquid stored therein may be adjusted secondarily. When the recovered treatment liquid is stored in the first tank 1100, the temperature sensor 1120 may measure the temperature of the recovered treatment liquid stored in the first tank 1100. The control unit 1600 may compare the temperature measurement value with a predetermined temperature. In this case, the temperature of the recovered treatment liquid stored in the first tank 1100 may not reach the predetermined temperature described above despite the addition of the heated treatment liquid, or in the process of moving along the discharge line L10 after addition of the treatment liquid, the temperature may decrease and may become lower than the predetermined temperature. In this case, the control unit 1600 may secondly control the temperature of the treatment liquid by heating the recovered treatment liquid in the first tank 1100 using the second heating unit 1110 and increasing the temperature to a predetermined temperature.

Thereafter, the concentration detection unit 1500 may detect whether the concentration of the recovered treatment liquid stored in the first tank 1100 is a predetermined concentration. In this case, when the concentration measurement value of the recovered treatment liquid corresponds to a predetermined concentration, the recovered treatment liquid may move to the second tank 1400 through the second transfer line U by the transfer pump. When the concentration measurement value of the recovered treatment liquid does not reach the predetermined concentration, the control unit 1600 may adjust the concentration of the recovered treatment liquid to reach the predetermined concentration by increasing the supply amount of treatment liquid, supplied by the treatment liquid supply unit 1200, and may move the treatment liquid to the second tank 1400.

Thereafter, the recovered treatment liquid (i.e., reprocessed treatment liquid) of which the concentration and the temperature have been adjusted may be temporarily stored in the second tank 1400 and may be supplied to the substrate processing apparatus 1 through the supply line L20. In this case, the reprocessed treatment liquid may be supplied back to the nozzle unit 400 and may be used in the process of processing the substrate W. Thereafter, the used reprocessed treatment liquid may be discharged from the substrate processing apparatus 1 as treatment liquid, may be partially discarded, and may also be partially recovered back to the first tank 1100 through the discharge line L10. By supplying new treatment liquid to the recovered treatment liquid, the process of being reused in the substrate supply device 1 may be repeated through the treatment liquid treatment process.

As for the method for processing treatment liquid, treatment liquid supply apparatus 1000, 1000a, 1000b, 1000c, 1000d, and 1000e and a substrate processing apparatus 1 including the same according to the embodiments described above, by supplying new treatment liquid from the substrate processing apparatus 1 to the discharge line L10 from which the treatment liquid is discharged, the concentration of the treatment liquid may be adjusted and stabilized before flowing into the first tank 1100. Also, before the new treatment liquid flows into the discharge line L10, the temperature may be increased in advance while passing through the first transfer line 1210, may be mixed with the treatment liquid, and may flow into the first tank 1100, such that the time required to control the temperature of the treatment liquid in the first tank 1100 may be reduced, and the overall speed of process of processing treatment liquid may increase.

According to the aforementioned embodiments, using the treatment liquid supply apparatus, the substrate processing apparatus and the method for processing treatment liquid including the same, by supplying new treatment liquid from the substrate processing apparatus to the discharge line in which the treatment liquid is discharged, before the treatment liquid flows into the first tank, the concentration of the treatment liquid may be adjusted to stabilize the liquid. Also, before the new treatment liquid flows into the discharge line, the temperature may be increased in advance while passing through the first transfer line, may be mixed with the treatment liquid and may flow into the first tank to reduce the time required to control the temperature of the treatment liquid in the first tank, such that the overall speed of the process of processing treatment liquid may increase.

While the embodiments have been illustrated and described above, it will be apparent to those skilled in the art that modifications and variations could be made without departing from the scope of the present disclosure as defined by the appended claims.

What is claimed is:

1. A treatment liquid supply apparatus, comprising:
a discharge line through which treatment liquid is discharged from a substrate processing apparatus;
a first tank storing recovered treatment liquid, recovered through the discharge line;
a treatment liquid supply unit supplying new treatment liquid to the discharge line through a first transfer line;
a first heating unit disposed between the treatment liquid supply unit and the discharge line and controlling a temperature of the new treatment liquid passing through the first transfer line; and
a second tank resupplying the recovered treatment liquid supplied from the first tank through a second transfer line to the substrate processing apparatus through a supply line.

2. The treatment liquid supply apparatus of claim 1,
wherein the discharge line is configured as a pipe for discharging the treatment liquid, disposed between the substrate processing apparatus and the first tank, and
wherein the first transfer line is a pipe for supplying the new treatment liquid, disposed between the treatment liquid supply unit and the discharge line.

3. The treatment liquid supply apparatus of claim 2,
wherein one end of the discharge line is connected to the substrate processing apparatus, and the other end of the discharge line is connected to the first tank, and
wherein one end of the first transfer line is connected to the treatment liquid supply unit, and the other end of the first transfer line is connected to the discharge line and is connected between the one end and the other end of the discharge line.

4. The treatment liquid supply apparatus of claim 3, wherein the first heating unit surrounds at least a portion of an external surface of the first transfer line.

5. The treatment liquid supply apparatus of claim 4, wherein the first heating unit is configured as a jacket heater.

6. The treatment liquid supply apparatus of claim 3, wherein the first tank includes a temperature sensor disposed in the first tank and measuring a temperature of the recovered treatment liquid stored in the first tank, and a second heating unit controlling a temperature of the recovered treatment liquid stored in the first tank.

7. The treatment liquid supply apparatus of claim 4, further comprising:
a concentration detection unit measuring a concentration of the recovered treatment liquid stored in the second tank through a first concentration measurement line,
wherein one end of the first concentration measurement line is connected to the supply line, and the other end of the first concentration detection line is connected to the concentration detection unit.

8. The treatment liquid supply apparatus of claim 7,
wherein the concentration detection unit further measures a concentration of the recovered treatment liquid stored in the first tank through a second concentration detection line, and
wherein one end of the second concentration detection line is connected to the second transfer line, and the other end of the second concentration detection line is connected to the concentration detection unit.

9. The treatment liquid supply apparatus of claim 1, wherein the treatment liquid discharged from the substrate processing apparatus sequentially passes through the first tank and the second tank and is supplied back to the substrate processing apparatus.

10. A method for processing treatment liquid, the method comprising:
discharging treatment liquid from a substrate processing apparatus through a discharge line;
supplying new treatment liquid to a discharge line by a treatment liquid supply unit;
adjusting a temperature of the new treatment liquid supplied to the discharge line by a first heating unit;
adjusting a temperature of the recovered treatment liquid recovered into the first tank through the discharge line to a predetermined temperature; and
transferring the recovered treatment liquid of which a concentration and a temperature are controlled to the second tank.

11. The method of claim 10, wherein the supplying new treatment liquid to a discharge line by a treatment liquid supply unit includes adjusting a concentration of the treatment liquid to a predetermined concentration by supplying the new treatment liquid before the treatment liquid flows into the first tank.

12. The method of claim 11, wherein the adjusting a temperature of the new treatment liquid supplied to the discharge line by a first heating unit includes heating the new treatment liquid to a predetermined temperature by the first heating unit and supplying the treatment liquid to the discharge line.

13. The method of claim 12, wherein the adjusting a temperature of the recovered treatment liquid recovered into the first tank through the discharge line to a predetermined temperature includes heating recovered treatment liquid to a predetermined temperature based on a temperature measurement value of the recovered treatment liquid stored in the first tank by the second heating unit.

14. The method of claim 13, wherein the adjusting a temperature of the recovered treatment liquid recovered into the first tank through the discharge line to a predetermined temperature includes heating the recovered treatment liquid to the predetermined temperature by the second heating unit when the temperature measurement value is lower than the predetermined temperature, and maintaining the recovered treatment liquid to be warm to maintain a temperature of the recovered treatment liquid when the temperature measurement value corresponds to the predetermined temperature.

15. The method of claim 13, wherein
measuring a concentration of the recovered treatment liquid stored in the second tank; and
adjusting the amount of treatment liquid supplied to the discharge line based on a concentration measurement value of the recovered treatment liquid.

16. The method of claim 15, wherein the adjusting the amount of treatment liquid supplied to the discharge line includes comparing a concentration measurement value of recovered treatment liquid in the second tank with a predetermined reference value, and increasing or decreasing the supply amount of treatment liquid.

17. The method of claim 15, further comprising:
measuring a concentration of the recovered treatment liquid stored in the first tank; and
calculating a difference in concentrations between the recovered treatment liquid in the first tank and the recovered treatment liquid in the second tank,
wherein the adjusting the amount of treatment liquid supplied to the discharge line includes increasing or decreasing the supply amount of treatment liquid, supplied to the discharge line, based on the calculated difference in concentrations.

18. The method of claim 17, wherein the adjusting the amount of treatment liquid supplied to the discharge line includes feedback-controlling the supply amount of treatment liquid such that the difference in concentrations does not exceed a predetermined reference value.

19. The method of claim 10, further comprising:
monitoring a concentration of the treatment liquid passing through the discharge line by measuring a concentration of the treatment liquid at a point at which the first transfer line is connected to the discharge line.

20. A substrate processing apparatus, comprising:
a process chamber;
a processing vessel disposed in the process chamber, accommodating a substrate therein, including a liquid outlet on a bottom surface thereof, and having an open upper portion;
a support unit supporting the substrate and including a support shaft disposed in the processing vessel and rotating, and a spin head connected to the support shaft;
a nozzle unit disposed on an external side of the processing vessel and including a moving nozzle device discharging treatment liquid to the substrate; and
a treatment liquid supply apparatus including a discharge line connected to the liquid outlet and discharging the treatment liquid, a first tank storing recovered treatment liquid, recovered through the discharge line, a treatment liquid supply unit supplying new treatment liquid to the discharge line through a first transfer line, a first heating unit disposed between the treatment liquid supply unit and the discharge line and controlling a temperature of the new treatment liquid passing through the first transfer line, and a second tank resupplying the recovered treatment liquid supplied from the first tank through a second transfer line to the substrate processing apparatus through a supply line,
wherein the discharge line is configured as a pipe for discharging the treatment liquid, disposed between the substrate processing apparatus and the first tank, and the first transfer line is configured as a pipe for supplying the new treatment liquid, disposed between the treatment liquid supply unit and the discharge line,
wherein one end of the discharge line is connected to the substrate processing apparatus, the other end of the discharge line is connected to the first tank, one end of the first transfer line is connected to the treatment liquid supply unit, and the other end of the first transfer line is connected to the discharge line and is connected between the one end and the other end of the discharge line,
wherein the first heating unit is configured as a jacket heater surrounding at least a portion of an external surface of the first transfer line, and
wherein the treatment liquid discharged from the processing vessel sequentially passes through the first tank and the second tank and is supplied back to the nozzle unit.
